(19) United States
(12) Patent Application Publication
(10) Pub. No.: US 2015/0235821 A1
(43) Pub. Date: Aug. 20, 2015

(54) UNIFORM FORCE FLANGE CLAMP

(71) Applicant: GENERAL PLASMA, INC., Tucson, AR (US)

(72) Inventors: John E. Madocks, Tucson, AZ (US); Ryan Lohrenz, Tucson, AZ (US); Steven Smith, SR., Tucson, AZ (US)

(73) Assignee: GENERAL PLASMA, INC., Tucson, AZ (US)

(21) Appl. No.: 14/429,667

(22) PCT Filed: Sep. 19, 2013
(86) PCT No.: PCT/US2013/060746

§ 371 Date: Mar. 19, 2015

Related U.S. Application Data
(60) Provisional application No. 61/703,249, filed on Sep. 19, 2012.

(51) Int. Cl. H01J 37/34; B25B 5/14; F16B 2/08

(52) U.S. Cl. CPC H01J 37/3435; F16B 2/08; B25B 5/147; H01J 37/3455

(57) ABSTRACT

A clamp is provided that incorporates a plurality of flexible links with V flexures between the links to maintain even spacing of the links before and during installation. Each link has multiple segments joined around at least one flexure point, and a floating band surrounding the links to distribute clamping pressure that is produced along a circumference of contact points. The clamp provides evenly distributed clamping pressure by increasing the number of clamping contact points between the clamp and articles being joined. The clamp has non-limiting applications for clamping target tubes or as a vacuum flange for ISO fittings. A clamp can produce a vacuum tight seal between a target tube and end block or end support flange of a rotary magnetron without resort to tools, and as such is rapidly secured in place.

### CROSS-REFERENCE TO RELATED APPLICATION

This application claims priority of United States Provisional Patent Application Ser. No. 61/703,249 filed Sep. 19, 2012, which is incorporated herein by reference.

### FIELD OF THE INVENTION

The present invention generally relates to clamps. More specifically, the present invention discloses a clamp incorporating a plurality of flexible links with ‘v’ flexures between the links to maintain even spacing of the links before and during installation, where each link has multiple segments joined at a center flexure point, and a floating band surrounding the links to adjust an evenly distributed clamping pressure that is produced along a circumference of contact points provided by the link segments.

### BACKGROUND OF THE INVENTION

The International Organization for Standardization that is widely known as ISO, is an international standard-setting body composed of representatives from various national standards organizations. The ISO promulgates worldwide proprietary, industrial, and commercial standards.

Among the standards promulgated by the ISO are standards for fasteners such as clamps. ISO clamps conform to measurements and dimensions that are defined by ISO reference standards. An application of ISO clamps include the joining of tubing.

It has been common in the art to use a split clamp retained with bolts to secure targets in rotary magnetrons. Split clamps have persistent problems in that it can be difficult to push the complementary clamp portions onto the flanges in sufficiently close proximity that the fasteners can be started. Often, technicians use a mallet to force this degree of clamp closure thereby causing undue damage to surrounding components, such as support shaft bearings. Another limitation of split clamps is that there are often only 2 or 4 points of contact between the outer split clamp halves and the joined articles such as target tube flanges in the context of a rotary magnetron; thereby placing undue stresses on the anchored article; that in the context of a rotary magnetron is the end block. Once fastened tightly, the split clamps can be difficult to remove and often a screwdriver is used to wedge the clamp portions apart and thereby causing undue wear on the flanges and the clamps. The non-uniform clamping force also distorts the jointed articles and in the context of a rotary magnetron: to the target tube thereby causing runout in target tube rotation.

Another conventional joinder is the use of threaded fasteners extending through the articles to be joined. This approach also suffers from serious limitations including the possibility that the fastener can loosen during operation, thereby causing catastrophic flooding of the vacuum chamber. Threaded fasteners are difficult to start and to tighten. Special tools are required and it is time-consuming to both tighten and loosen the fasteners.

In spite of the prior art efforts, there remains a need for improved clamp designs that provide uniform clamping pressure along the circumference of a tube or pipe to be joined to an adjoining flange or fitting.

### SUMMARY OF THE INVENTION

A clamp is provided that incorporates a plurality of flexible links with ‘v’ flexures between the links to maintain even spacing of the links before and during installation. In embodiments of the inventive clamp, each link has multiple segments joined at a center flexure point, and a floating band surrounding the links to adjust an evenly distributed clamping pressure that is produced along a circumference of contact points provided by the link segments. Embodiments of the present inventive clamp provide evenly distributed clamping pressure by increasing the number of clamping contact points between the inventive clamp and an application device or apparatus to be secured. Embodiments of the inventive clamps have non-limiting applications for clamping target tubes or as a vacuum flange for ISO fittings. Embodiments of the inventive clamp produce a vacuum tight seal between a target tube and end block or end support flange without requiring tools, and is very fast to apply and use by a technician.

Embodiments of the inventive clamp employ a floating band that is not attached to the links. In embodiments, as the floating band is tightened the links are not pulled around with the band itself, as encountered in previous designs that provide an uneven clamping force and made the previous clamps unusable for many applications such as in a rotary magnetron. The ‘v’ flexures between the links of the inventive clamp act to keep the links evenly apart before and during installation and tightening of the floating band. The ‘v’ flexures work to keep the links positioned, and also allow the links to move inward without binding. The ‘v’ flexures are also vacuum and high heat compatible.

Embodiments of the inventive clamp utilize stabilizer pins at the clamp handle. The stabilizer pin prevents an undesirable condition when rotating the handle down, where the downward force on the handle causes that link to dig down and ‘over clamp’ that portion of the flange, and as tightening progresses clamping pressures do not even out and the end result is uneven clamping on the flange, with clamping pressure greater near the handle.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings wherein like reference numerals refer to like parts throughout the several views, and in which:

FIGS. 1A and 1B are perspective views of an existing clamp with non-flexing segmented links;

FIG. 2 is a top perspective view of a flexible link clamp according to an embodiment of the present invention;

FIG. 3 is an exploded perspective view of the inventive clamp of FIG. 2 according to an embodiment of the invention;

FIG. 4A is a cross-sectional view of the inventive clamp of FIG. 2 along line A-A according to an embodiment of the invention;

FIG. 4B illustrates a detail B of the tightening clasp of cross-sectioned clamp view of FIG. 4A;

FIGS. 5A and 5B are perspective views of inventive clamp of FIG. 2 with a protective cover;

FIG. 5C is a cross-sectional view of FIG. 5B along line C-C showing the inventive clamp within the protective cover according to an embodiment of the invention;

FIG. 6 illustrates a non-limiting application of the inventive clamp of FIG. 2 for securing a target tube within a rotary magnetron;

FIG. 7 illustrates the inventive clamp of FIG. 2 securing the target tube to the end brush assembly of the rotary magnetron;

FIG. 8 illustrates the inventive clamp of FIG. 2 securing the target tube to the rotary motor; and

FIG. 9 illustrates the inventive clamp of FIG. 2 with the protective cover with the target tube secured to the brush assembly of the rotary magnetron.

The detailed description explains the preferred embodiments of the invention.

### DESCRIPTION OF THE INVENTION

The present invention has utility as a clamp. The present invention discloses a clamp incorporating a plurality of flexible links with ‘v’ flexures between the links to maintain even spacing of the links before and during installation, where each link has at least two segments joined around at least one flexure point, and a floating band surrounding the links to adjust the distribution of clamping pressure that is produced along a circumference of contact points with the articles being joined. An inventive clamp has the benefits multiple contact points around sealing flanges thereby reducing deformation on the jointed articles; more uniform clamping force at each contact point; no necessity for tools to engage or disengage the clamp and therefore is quicker to deploy and remove; compliant members between links keeps links properly spaced at initial installation and then allow links to move inward, and closer together, as they are tightened around a joinder.

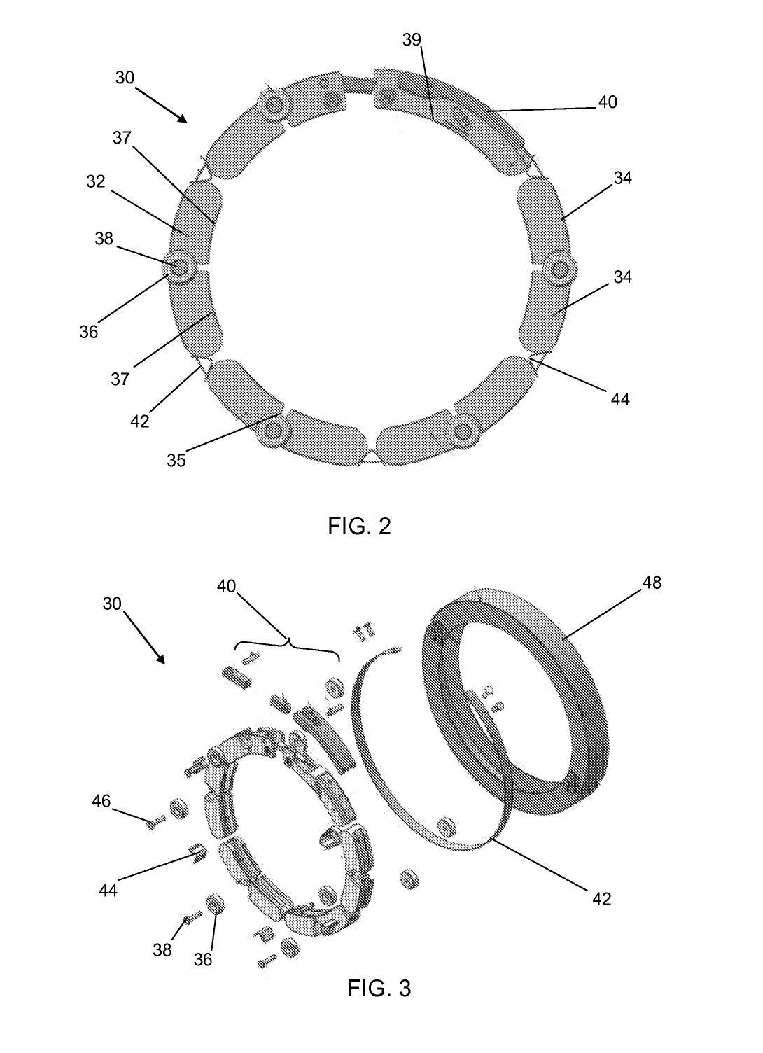

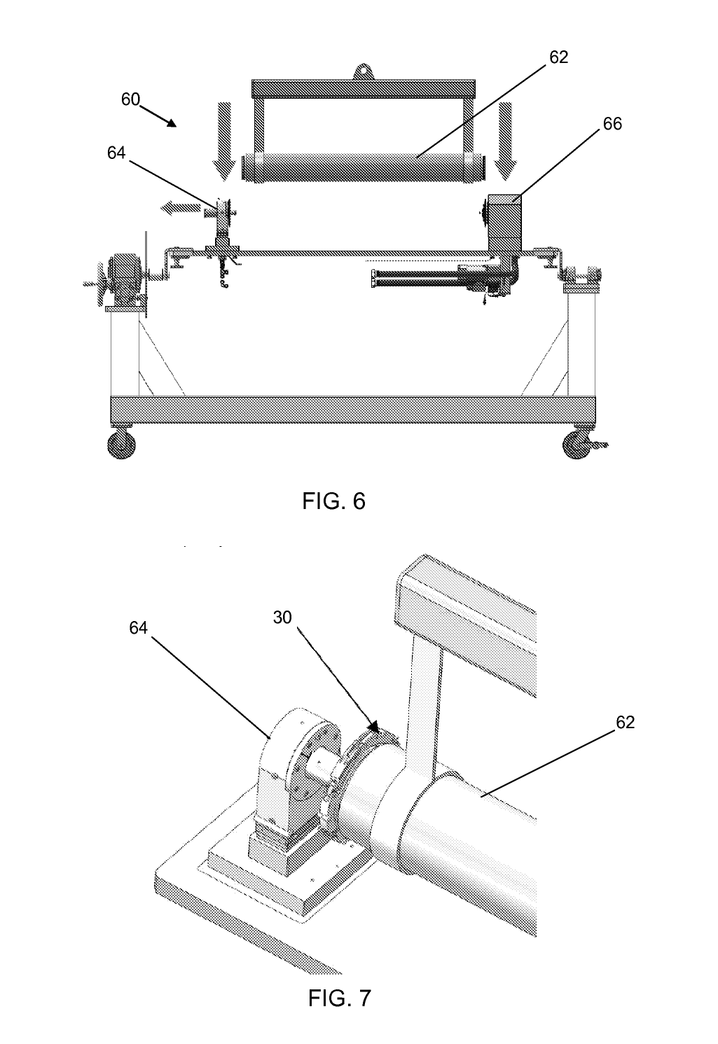

Embodiments of the present inventive clamp provide evenly distributed clamping pressure by increasing the number of clamping contact points between the inventive clamp and an application device or apparatus to be secured. For example, commonly used split clamps, given tolerance stack ups, only provide two flange/clamp contact points. With an embodiment of the present inventive clamp as shown in FIGS. 2-5, five links with each link having a center flexure point, provides ten contact points in addition the handle or clasp link. In further embodiments additional links may be provided to support additional contact points, and/or the links may be subdivided into more segments with additional flexure points, for example a link with three segments configured with two flexure points. Multiple contact points are critical for applications where it is important to reduce bending and high stresses of the application device or apparatus to be secured. Embodiments of the inventive clamps have non-limiting applications for clamping target tubes or as a vacuum flange for ISO fittings. Embodiments of the inventive clamp produce a vacuum tight seal between a target tube and end block or end support flange without requiring tools, and is very fast to apply and use by a technician, as will be shown below in FIGS. 6-9.

Embodiments of the inventive clamp employ a floating band that is not attached to the links. In embodiments, as the floating band is tightened the links are not pulled around with the band itself. In previous design instances where the links are pulled around when tightened, the inward clamping force is reduced by the friction force pulling the link in the tightening direction, and an uneven clamping force is produced around the flange. An uneven clamping force encountered in previous link clamp designs made these clamps unusable for many applications such as in a rotary magnetron. The sliding band and floating links of the present invention eliminate this problem. Embodiments of the inventive clamps have ‘v’ flexures between the links to keep the links evenly apart before and during installation and tightening of the floating band. The ‘v’ flexures work to keep the links positioned, and also allow the links to move inward without binding. The ‘v’ flexures are also vacuum and high heat compatible.

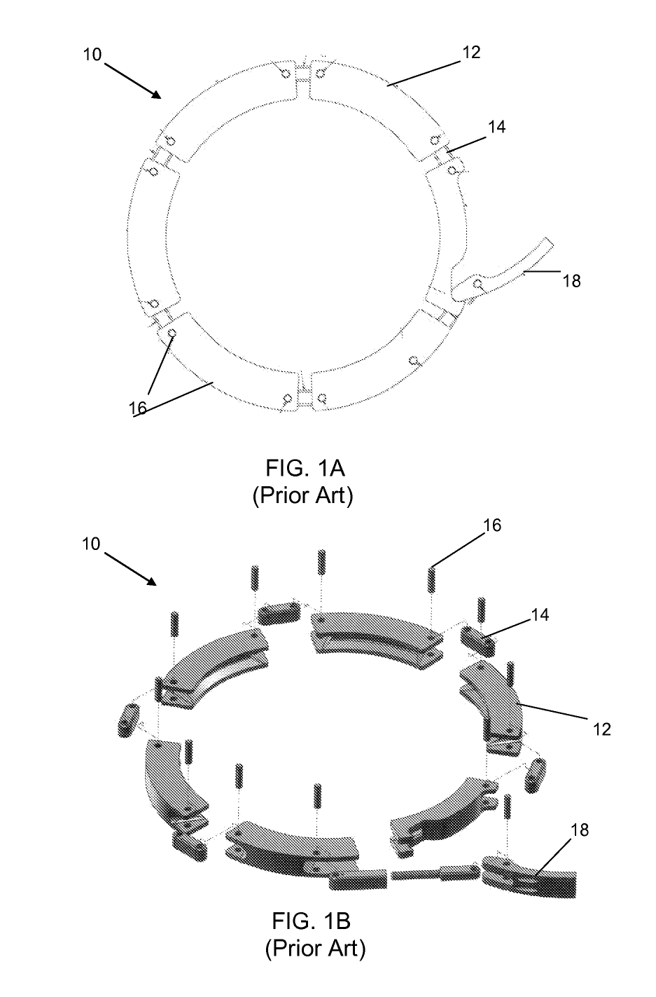

Embodiments of the inventive clamp utilize stabilizer pins at the clamp handle. In embodiments, the stabilizer pin prevents an undesirable condition when rotating the handle down, where the downward force on the handle causes that link to dig down and ‘over clamp’ that portion of the flange, and as tightening progresses clamping pressures do not even out and the end result is uneven clamping on the flange, with clamping pressure greater near the handle. FIGS. 1A and 1B illustrate an existing clamp 10 with non-segmented links 12 connected with joiners 14 via pins 16, which fails to provide even clamping pressure as described above when downward pressure is applied to the handle 18. However, the problem associated with the downward force on the handle is avoided in embodiments of the present invention with the aforementioned stabilizing pins, where the stabilizing pins hit the top of the flanges thereby preventing further digging in and allowing the other links to pull in for a uniform seal.

Embodiments of the inventive clamp are compact with a small outside radius, which is important in tight applications, such as in rotary magnetrons where space is very limited in the chambers and shields and other components are very close to the spinning rotary target tubes, as will be shown in FIGS. 6-9.

Embodiments of the inventive clamp also have an optional shield cover. In a non-limiting application of the inventive clamp, an electrically floating shield covers the link clamp from getting covered in sputter debris. The clamp has no protruding parts so the shield cover can be annular and compact. In an embodiment, the shield may be set off the clamp by alumina insulators. In an additional embodiment, the shield could also be just metal on metal with the inventive clamp.

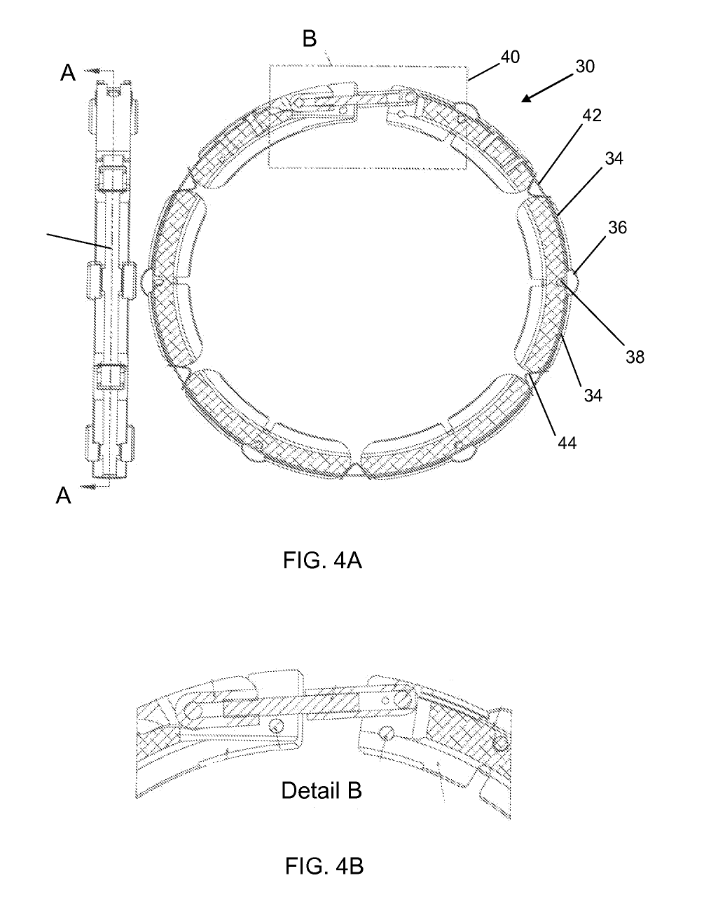

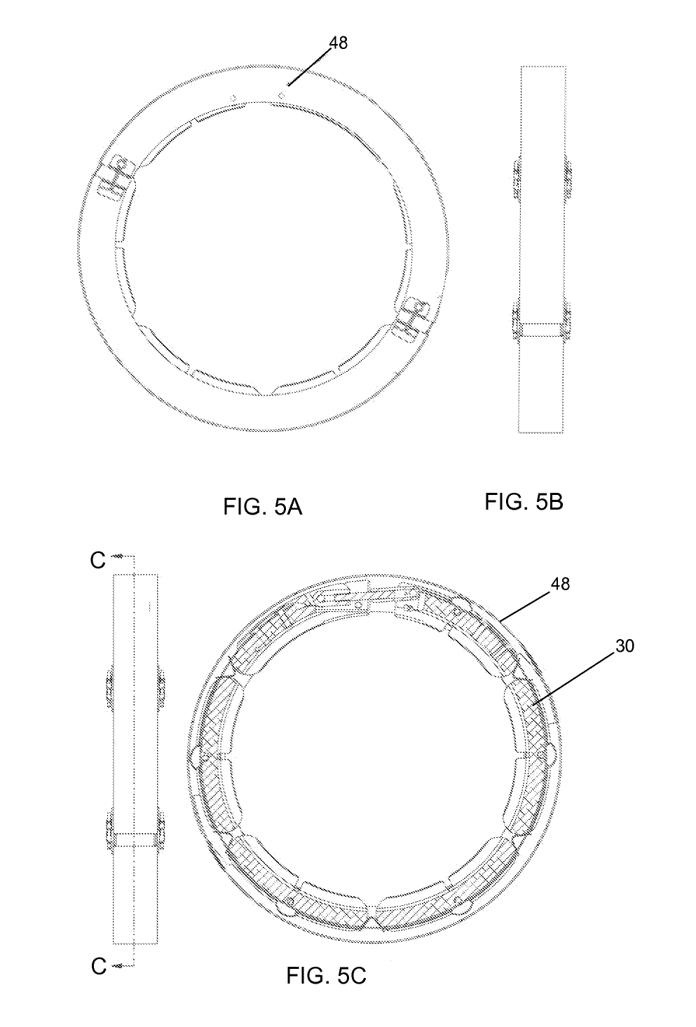

Referring to FIGS. 2-5, an embodiment of the inventive clamp is shown at 30 with five links 32, with each link 32 having segments 34 positioned about a center flexure point 35, which provides ten contact points or surfaces 37 in addition to the contact surface 39 of the handle or clasp link 40. In further embodiments additional links may be provided to support additional contact points, and/or the links may be subdivided into more segments with additional flexure points, for example a link with three segments configured with two flexure points (not shown). Flexure points 35 between segments 34 have pivot pins 36 inserted through washers 38 for joining the segments 34 in a flexible and pivoting manner. A floating band 42 that is not attached to the links 32 is fixedly attached to the clasp link 40, which is shown in greater detail in FIG. 4B, for tightening the inventive clamp 30. In embodiments, as the floating band 42 is tightened the links 32 are not pulled around with the band 42 itself thereby providing an even inward clamping force along the contact surfaces 37 and 39. In addition, clamp 30 has ‘v’ flexures 44 between the links 32 to maintain an even spacing between the links 32 before and during installation and tightening of the floating band 42. The ‘v’ flexures 44 work to keep the links 32 positioned, and also allow the links 32 to move inward without binding. The ‘v’ flexures 44 are also vacuum and high heat compatible. Protective cover or shield 48 prevents debris from accumulating in the clamp 30, such sputter debris as described below with respect to the magnetron application of FIGS. 6-9. FIGS. 5A and 5B are perspective views of the clamp 30 within the protective cover 48, with FIG. 5C providing a cross-sectional view of FIG. 5B along line C-C showing the clamp 30 within the protective cover according to an embodiment of the invention.

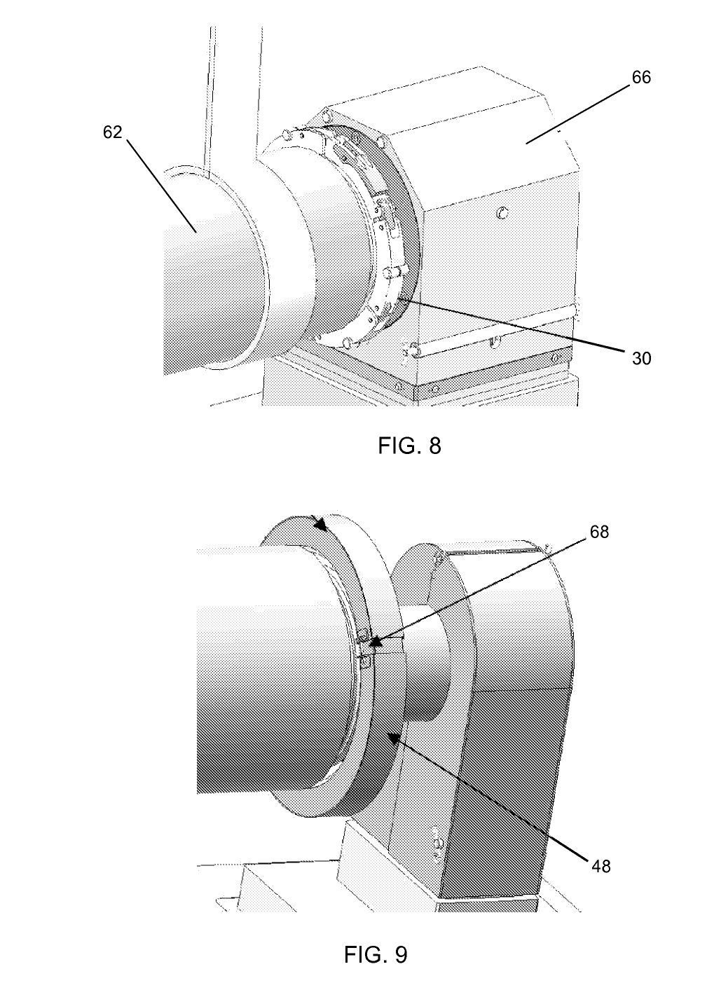

FIG. 6 illustrates a non-limiting application of the inventive clamp 30 securing a target tube 62 within a rotary magnetron 60. In FIG. 6, a target tube 62 is being lowered into a rotary magnetron 60 for attachment to an end brush assembly 64 and rotary motor 66 with clamp 30. FIG. 7 illustrates the clamp 30 securing the target tube 62 to the end brush assembly 64 of the rotary magnetron 60. FIG. 8 illustrates the clamp 30 securing the target tube to the rotary motor 66. FIG. 9 illustrates clamp 30 with the protective cover 48 securing the target tube 62 to the end brush assembly 64 of the rotary magnetron 60. The protective cover 48 is secured together with wire 68.

A process is provided by two articles are joined together by bring the two articles into terminal end contact to form a joint. An inventive clamp is used to circumvent the joint. By tightening the clamp, a superior degree of external clamping pressure uniformity is achieved relative to conventional clamps. With resort to conventional force sensors, the pressure applied by the clamp at multiple points on a surface of the joint is monitored.

The foregoing description is illustrative of particular embodiments of the invention, but is not meant to be a limitation upon the practice thereof. The following claims, including all equivalents thereof, are intended to define the scope of the invention.

1. A clamp comprising:
a plurality of flexible links, each link having at least two segments joined around at least one flexure point;
a tightening clasp mechanically coupled to one of said plurality of flexible links;
a floating band fixedly connected to said tightening clasp, said floating band in movable contact and surrounding said flexible links to distribute inward clamping pressure that is produced along a circumference of contact surfaces; and
‘v’ flexures between said plurality of flexible links to maintain an even spacing of plurality of flexible links during adjustments of said clamp.

2. The clamp of claim 1 wherein each of said plurality of flexible links provides two contact surfaces.

3. The clamp of claim 1 wherein said two segments pivot about a pin at said center flexure point.

4. The clamp of claim 1 wherein said ‘v’ flexures are vacuum and high heat compatible.

5. The clamp of claim 1 wherein said tightening clasp further comprises stabilizer pins.

6. The clamp of claim 1 wherein said clamp has a protective cover shield.

7. The clamp of claim 6 wherein said protective cover shield is set off said clamp by alumina insulators.

8. The clamp of claim 1 wherein said clamp secures a target tube in a rotary magnetron.

9. The clamp of claim 1 wherein said plurality of flexible links has 6 links.

10. The clamp of claim 1 wherein said clamp is a vacuum flange for International Organization for Standardization (ISO) fittings.

11. A process of joining two articles comprising:
bring the two articles into terminal end contact to form a joint;
circumventing said joint with a clamp of claim 1; and
tightening said clamp around said joint.

12. The process of claim 11 wherein the two articles are tubes.

13. The process of claim 11 further comprising monitoring the pressure applied by the clamp at multiple points on a surface of the joint.

14. The process of claim 11 wherein said tightening is accomplished without tools.

15. The process of claim 11 wherein said tightening occurs with a band surround the clamp.

16. The process of claim 11 wherein one of the two articles is a target tube and another of the two articles is a brush assembly or rotary motor of a rotary magnetron.

17. A rotary magnetron comprising:
a target tube;
a brush assembly;
a rotary motor in mechanical communication with said brush assembly;
a power source for generating a plasma adjacent to said target tube; and
a clamp of claim 1 joining said target tube to said brush assembly.

18. The rotary magnetron of claim 17 further comprising a protective cover secured to said clamp.
